(19) United States
(12) Patent Application Publication
(10) Pub. No.: US 2026/0354228 A1
(43) Pub. Date: Nov. 5, 2026

(54) SUBSTRATE, POWER SEMICONDUCTOR ARRANGEMENT, AND METHOD FOR PRODUCING A POWER SEMICONDUCTOR ARRANGEMENT

(71) Applicant: SMA Solar Technology AG, Niestetal (DE)

(72) Inventors: Gerrit Braun, Kassel (DE); Klaus Rigbers, Göttingen (DE)

(21) Appl. No.: 19/710,498

(22) Filed: Jun. 17, 2026

Related U.S. Application Data
(63) Continuation of application No. PCT/EP2024/086397, filed on Dec. 13, 2024.

(30) Foreign Application Priority Data
Dec. 20, 2023 (DE) 10 2023 136 151.1

(51) Int. Cl. H10W 70/65; H02M 7/00; H10W 40/20; H10W 42/20; H10W 70/695; H10W 90/00

(52) U.S. Cl. CPC H10W 70/65; H10W 40/235; H10W 42/20; H10W 70/695; H10W 90/734; H02M 7/003

(57) ABSTRACT

The disclosure relates to a substrate having at least one soldering surface, wherein the substrate is provided to be equipped with a power semiconductor; for equipping, the soldering surface is bonded to the power semiconductor by a soldering process; a main body of the substrate including at least one substrate material having a high thermal conductivity and/or a high electrical dielectric strength; and the substrate is configured to have a heat-dissipating and/or electromagnetically shielding effect with respect to the power semiconductor. The disclosure also relates to a power semiconductor arrangement including such a substrate, to a method for producing a power semiconductor arrangement, and to an inverter including a power semiconductor arrangement.

### REFERENCE TO RELATED APPLICATIONS

This application is a Continuation of International Application number PCT/EP2024/086397, filed on Dec. 13, 2024, which claims the benefit of German Application number 10 2023 136 151.1, filed on Dec. 20, 2023. The contents of the above-referenced Patent Applications are hereby incorporated by reference in their entirety.

### FIELD

This disclosure relates to packaging and interconnection technology for power-electronic circuits. This disclosure relates in particular to a substrate that is provided for equipping with a power semiconductor, to a power semiconductor arrangement having such a substrate and to a method for producing a power semiconductor arrangement. Power semiconductors are semiconductor components that are designed for switching high electrical currents and voltages.

### BACKGROUND

DE102019133377A1 describes an inverter comprising a power semiconductor arrangement with two printed circuit boards. A first printed circuit board is connected to a heat sink, and the second printed circuit board is mounted on a sheet-metal element, wherein the sheet-metal element has, among other things, an electromagnetic shielding function.

DE102021110251A1 describes a power semiconductor arrangement comprising two printed circuit boards and a power semiconductor arranged therebetween. Here, the power semiconductor can be designed as an SMD component (SMD=surface mounted device).

SMD components (surface-mounted components) can be electrically contacted on the surface of printed circuit boards. For this purpose, they have a contacting side on which electrical terminals are arranged. The electrical terminals arranged on the contacting side are provided for contacting with conductor tracks on a printed circuit board. The contacting can be effected, e.g., by means of a soldered bond, which may simultaneously establish the mechanical fastening on the printed circuit board.

### SUMMARY

The disclosure is directed to a power semiconductor arrangement with improved properties and/or an improved method for producing a power semiconductor arrangement.

A substrate according to the disclosure is provided for equipping with a power semiconductor. The term ‘substrate’ as used herein denotes a body configured to support and/or cover the power semiconductor device and to thermally and/or electrically interact with the power semiconductor device. A power semiconductor can comprise, e.g., a diode of silicon, silicon carbide or gallium arsenide and/or a transistor of silicon, silicon carbide or gallium nitride, along with, if applicable, associated driver functionalities.

The substrate has at least one soldering surface, wherein, for equipping the substrate with the power semiconductor, the soldering surface is designed to be bonded to the power semiconductor by a soldering process. The substrate has a main body, which comprises at least one substrate material having a high thermal conductivity and/or a high electrical dielectric strength. The substrate is designed to have a heat-dissipating and/or electromagnetically shielding effect with respect to the power semiconductor.

By suitably selecting a substrate material for the main body, the desired effect of the substrate can be achieved. If the substrate material of the main body is selected, e.g., so that it has a high thermal conductivity, the main body of the substrate has a heat-dissipating effect. If the substrate material of the main body is selected, e.g., so that it has a high electrical dielectric strength, the main body of the substrate additionally has a good insulating effect. The substrate material for the main body of the substrate can also be selected so that a high thermal conductivity and additionally good insulation with a high electrical dielectric strength are achieved.

The substrate has the advantage that, in addition to the described property or the described properties, it comprises the at least one soldering surface, which makes it possible to equip the power semiconductor on the substrate or, conversely, to equip the power semiconductor with the substrate. With the resulting arrangement, the power semiconductor can benefit from the properties of the substrate, e.g., from the heat dissipation and/or the electromagnetic shielding. The mechanical connection between the power semiconductor and the substrate is established by the soldered bond, in that the soldering surface is provided as a surface on which the power semiconductor can be soldered. Soldering the power semiconductor to the soldering surface can be effected, e.g., by means of solder paste or a preformed solder piece.

In one embodiment of the substrate, the soldering surface is provided for equipping with a power semiconductor which is designed as an SMD component. The equipping comprises mechanically connecting the SMD component to the substrate, so that the SMD component can benefit from the properties of the substrate, e.g., from the heat dissipation and/or the electromagnetic shielding. The SMD power semiconductor can comprise a housing with a plurality of sides. On at least one side of the housing, the SMD power semiconductor can have electrical terminals for contacting. In this respect, this contacting side of the SMD power semiconductor is provided for electrical contacting with a printed circuit board, which can have, e.g., further components for realizing a power-electronic semiconductor circuit. The SMD power semiconductor can be bonded to the soldering surface of the substrate by means of solder on another side of the housing. The SMD power semiconductor can be designed, e.g., as a semiconductor switch that is suitable for switching high currents.

In one embodiment of the substrate, the soldering surface is provided for connection to a side of the SMD power semiconductor that is provided for heat dissipation. If the SMD component has such side for heat dissipation, the connection to the substrate provided via the soldering surface can further support heat dissipation. Particularly in the case of a substrate having high thermal conductivity, heat dissipation from the SMD power semiconductor can thus be further improved, for example, when the substrate is thermally conductively connected to a heat sink.

The SMD power semiconductor can be designed, e.g., as a power semiconductor switch and comprise a contacting side with electrical terminals, which are provided for contacting with a printed circuit board and which can be actuated via the semiconductor. In one embodiment, the side of the SMD power semiconductor provided for heat dissipation is arranged opposite the contacting side with these switching contacts of the SMD power semiconductor. The power loss heat generated during switching operations in the power semiconductor can be dissipated to the side provided for heat dissipation, which lies opposite the contacting side. Such SMD power semiconductors can be designed, for example, as TSC (top-side cooled) components.

In one embodiment, the substrate can have a plurality of separate soldering surfaces, which are provided for the respective connection to different power semiconductors.

In one embodiment, the substrate comprises at least one recess for receiving a respective mounting structure or means, wherein the respective mounting structure or means is, for example, provided for mechanically connecting the substrate to a printed circuit board. The at least one recess for receiving the mounting means can in particular be designed as a through-recess. The printed circuit board can, in one embodiment, be configured to be electrically conductively connected to the switching contacts of the power semiconductor.

In embodiments of the substrate, the at least one substrate material comprises ceramic, plastic and/or composite material. The composition of the substrate material is selected in one embodiment such that the desired property with respect to thermal conductivity and/or electromagnetic shielding is achieved.

In one embodiment of the substrate, the soldering surface comprises or is designed as a copper layer. The good thermal conductivity of copper can improve the desired effect with regard to thermal conductivity and/or electrical shielding.

In one embodiment, the substrate comprises at least one cavity. In one embodiment, the main body of the substrate can have the at least one cavity. The at least one cavity is designed, e.g., as a blind recess in the substrate main body. The at least one soldering surface of the substrate is then arranged in a respective cavity. The power semiconductor can then be placed in the cavity during the equipping operation. In one embodiment, the depth of the at least one cavity is selected so that it terminates flush with the power semiconductor if the latter is arranged in the particular cavity.

In embodiments, the thickness of the substrate differs by less than 1 mm, for example, by less than 300 μm, from the thickness of the power semiconductor, wherein the substrate can have different thicknesses over its extent. The thickness of the substrate at the soldering surfaces can be less than 1 mm, for example, less than 200 μm.

In embodiments, the substrate comprises a plurality of layers, each layer comprising at least one different substrate material. By designing the substrate with a plurality of layers of different substrate materials, the desired properties of the substrate can be further improved. For example, the substrate materials can be selected so that they differ with regard to, e.g., thermal conductivity and/or electrical dielectric strength and/or magnetic shielding.

In one embodiment, the substrate can comprise a layer that is designed as a shielding layer providing an electromagnetically shielding effect. In one embodiment, the shielding layer can comprise a metal, e.g., copper, which can dissipate interference currents to a substantially constant potential. In one embodiment, the shielding layer can be arranged in the substrate between the soldering surface and the side of the substrate opposite the power semiconductor. The shielding layer can extend laterally over the entire substrate or only over partial regions of the substrate.

The EMC shielding (EMC=electromagnetic compatibility) achieved by dissipating interference currents by the shielding layer is advantageous, e.g., in the case of rapidly switching half-bridges. In one embodiment, if the SMD power semiconductor is arranged via the substrate on a heat sink having a substantially quiet potential, interference currents that are possibly capacitively coupled in between the SMD power semiconductor and the heat sink can arise. Such capacitively coupled interference currents can be dissipated directly by the additional shielding layer, e.g., copper layer, in the substrate, and it can be achieved that the interference currents no longer reach the heat sink connected to the substrate.

In one embodiment, the substrate can comprise at least two soldering surfaces, wherein the shielding layer extends in the substrate over the at least two soldering surfaces, i.e., lies between both soldering surfaces, respectively, and the heat sink. As a result, shielding can be achieved for both of the power semiconductors that can be equipped on the respective soldering surfaces.

When used in a power converter designed as a DC/DC converter or DC/AC converter, the shielding layer can be connected to one of the DC voltage potentials DC+ or DC− or to a center potential M in order to dissipate capacitively coupled interference currents (=common-mode interference) that can occur, e.g., between the switching-node potential of a particular power semiconductor and the essentially fixed potential of the heat sink or the ground potential. The potential of the shielding layer can be connected, e.g., to M, DC−, or DC+ and selected so that it hardly varies relative to ground. Thus, interference caused by capacitive interference currents or leakage currents can be significantly reduced.

In one embodiment, the substrate comprises, on the side of the power semiconductor, an electrical contact to the shielding layer. Via such contact, the potential level of the shielding layer and thus the shielding effect of the shielding layer can be optimized. For example, by connecting the shielding layer to a potential which is substantially constant with no or slow potential fluctuations during operation, the shielding effect can be improved.

In an alternative embodiment of the substrate, the shielding layer is electrically connected to one of the soldering surfaces. This is advantageous if this one soldering surface is already connected to a substantially constant potential (DC+, DC−, or M), for example via the power semiconductor and its switching contacts, and thus a separate connection to a constant potential can be dispensed with.

The shielding layer can be configured as one piece with one of the soldering surfaces as a copper layer and extend under the other soldering surface. In such an embodiment, the copper layer, which comprises a soldering surface for one power semiconductor and extends under the soldering surface of another power semiconductor, acts as a shielding layer in one embodiment for the second power semiconductor.

In one embodiment of the substrate, the soldering surface is equipped with solder. In one embodiment, the solder can comprise solder paste or a preformed solder piece, a so-called preform. The soldering surface can be printed, e.g., with solder paste. By providing the solder on the soldering surface, equipping the substrate can be further simplified.

A power semiconductor arrangement according to the application comprises at least one power semiconductor and the described substrate. Depending on the manufacturing sequence used, the substrate can be equipped with the at least one power semiconductor or, conversely, the power semiconductor can be equipped with the substrate.

In one embodiment, the power semiconductor arrangement further comprises a printed circuit board, with which the at least one power semiconductor is electrically conductively connected via its switching contacts.

In one embodiment, the substrate of the power semiconductor device is connected to a heat sink via a transfer layer. Via the transfer layer, e.g., a thermally conductive paste, the substrate is in better thermal connection with the heat sink.

In one embodiment of the power semiconductor arrangement, the at least one power semiconductor is bonded by a solder to the soldering surface in at least one cavity of the substrate, and the power semiconductor is electrically conductively connected to the printed circuit board on the side opposite the substrate, wherein the substrate bears against the printed circuit board in regions different from the at least one cavity. This embodiment is particularly advantageous for SMD semiconductors designed as TSC (top-side cooled) components. The heat generated by the power semiconductor can be dissipated to the side provided for heat dissipation, which lies opposite the contacting side and thus opposite the printed circuit board.

In one embodiment of the power semiconductor arrangement, the shielding layer is electrically connected to a potential of the power semiconductor arrangement which is substantially constant during operation. As a result, the voltage level can advantageously be selected so that, e.g., insulation layer thicknesses can be minimized.

A further power semiconductor arrangement according to the application comprises at least one SMD power semiconductor and a substrate having at least one soldering surface. A main body of the substrate comprises at least one substrate material having a high thermal conductivity and/or a high electrical dielectric strength. The substrate is designed to have a heat-dissipating and/or electromagnetically shielding effect with respect to the SMD power semiconductor.

A method for producing a power semiconductor arrangement as outlined above comprises equipping the substrate with the at least one SMD power semiconductor by placing the SMD power semiconductor onto the soldering surface, or equipping the substrate by placing the substrate with the soldering surface onto the SMD power semiconductor.

In embodiments of the method, the soldering surface is placed onto a side of the SMD power semiconductor that is provided for dissipating power loss of the SMD power semiconductor, wherein said side of the SMD power semiconductor provided for heat dissipation lies opposite a contacting side with switching contacts of the SMD power semiconductor.

In embodiments of the method, a side of the SMD semiconductor that is provided for dissipating power loss of the SMD power semiconductor is placed onto the soldering surface, wherein said side of the SMD power semiconductor provided for heat dissipation lies opposite a contacting side with switching contacts of the SMD power semiconductor.

In one embodiment of the method, after equipping the substrate, the SMD power semiconductor is bonded to the soldering surface by means of solder arranged on the soldering surface by a soldering process. The bond by the soldering process is effected between the side of the SMD power semiconductor and the soldering surface, which were placed on top of one another in the preceding step.

In embodiments of the method, the soldering surface is bonded by the soldering process to the side of the SMD power semiconductor that is provided for heat dissipation of power loss of the SMD power semiconductor and lies opposite a contacting side with switching contacts of the SMD power semiconductor.

In one embodiment of the method, after equipping the substrate and bonding the substrate to the SMD power semiconductor by the soldering process, equipping of a printed circuit board with the SMD power semiconductor is performed by placing the at least one SMD power semiconductor onto the printed circuit board.

In one embodiment of the method, the SMD power semiconductor is bonded to the printed circuit board by a soldering process before or after equipping with the substrate.

The soldering process for equipping the substrate or for bonding to the printed circuit board can comprise, e.g., a reflow soldering process. Reflow soldering is a soft-soldering process that is suitable for soldering SMD components. In reflow soldering, a soft solder is applied to the substrate or the printed circuit board prior to equipping, for example by means of stencil printing, as a solder preform, or also galvanically. After the solder has been applied, the components are equipped, wherein the components can adhere directly to the applied paste during equipping, so that additional adhesive bonding can be dispensed with. The equipped printed circuit board is then heated strongly enough for the solder to melt. The heating methods used in reflow soldering are intended to heat the printed circuit board and the components as uniformly as possible.

In one embodiment the soldering processes of the method can be performed individually one after another or in one step. It is possible, e.g., for the soldering process for bonding the substrate to the SMD power semiconductor to be performed before or after the soldering process for bonding the SMD power semiconductor to the printed circuit board, or for the SMD power semiconductor to be bonded to the substrate and the printed circuit board in one step.

With the described method, a soldered connection can be effected between the printed circuit board and the contacting side of the power semiconductor on one side, and a soldered connection can be effected between another side of the power semiconductor, in particular the heat-dissipating side in the case of TSC SMD power semiconductors, and the substrate. The substrate has soldering surfaces and is in one embodiment suitable for equipping in the SMT process (SMT=surface mount technology).

The described power semiconductor arrangement can be used, for example, in power converters that convert electrical power in the range of a few kilowatts to several hundred kilowatts at voltages of several hundred volts between direct current and alternating current. Examples of power semiconductors in power converters are semiconductor switches in DC/DC circuits, DC/AC circuits or AC/AC circuits. Power converters can comprise power semiconductor arrangements in different topologies, e.g., half-bridge or full-bridge circuits, B6 bridge circuits or so-called flying-cap topologies, and can, if applicable, be operated bidirectionally. Power converters configured as DC/AC converters are also referred to as inverters.

An inverter can comprise a power semiconductor arrangement as disclosed, wherein the power semiconductor arrangement comprises a DC/DC or DC/AC circuit, which comprises the at least one SMD power semiconductor.

Bridge circuits in inverters, so-called inverter bridges, can be configured in single-phase and three-phase inverters, both as single-phase and as three-phase, and comprise a corresponding number of power semiconductor arrangements.

In one embodiment of the inverter, the inverter has a rated electrical power of at least one kilowatt. The at least one SMD power semiconductor can be configured as a power switch that is designed for switching a maximum electrical current of at least 10 amperes at a maximum voltage of at least 500 volts.

The substrate of the power semiconductor arrangement of the inverter can comprise at least two power switches designed as SMD power semiconductors. One of the SMD power semiconductors can be designed for switching a substantially constant potential of the particular bridge circuit that is connected to its switching contacts. One of the power switches can also be electrically connected on its side provided for heat dissipation to the shielding layer. The other power switch can be designed for switching a variable potential, in particular a potential of the particular bridge circuit that jumps between different potential values during operation of the inverter. In such an embodiment, the shielding layer connected to the substantially constant potential, due to its extension over the power switch or switches that jump between the different potential values, can improve the electromagnetic shielding of the bridge circuit relative to the heat sink.

### BRIEF DESCRIPTION OF THE FIGURES

The disclosure is further explained and described below with reference to example embodiments illustrated in the figures.

FIGS. 1a-1d schematically shows various embodiments of a substrate.

FIGS. 2a-2d schematically shows various embodiments of the substrate with power semiconductors.

FIG. 3 schematically shows a first embodiment of a power semiconductor arrangement.

FIG. 4 schematically shows a second embodiment of the power semiconductor arrangement.

FIG. 5 schematically shows a third embodiment of the power semiconductor arrangement.

FIGS. 6a-6d schematically shows embodiments of a method for producing a power semiconductor arrangement.

The same reference signs are used in the figures for identical or similar elements. The representations in the figures may not be to scale.

### DETAILED DESCRIPTION

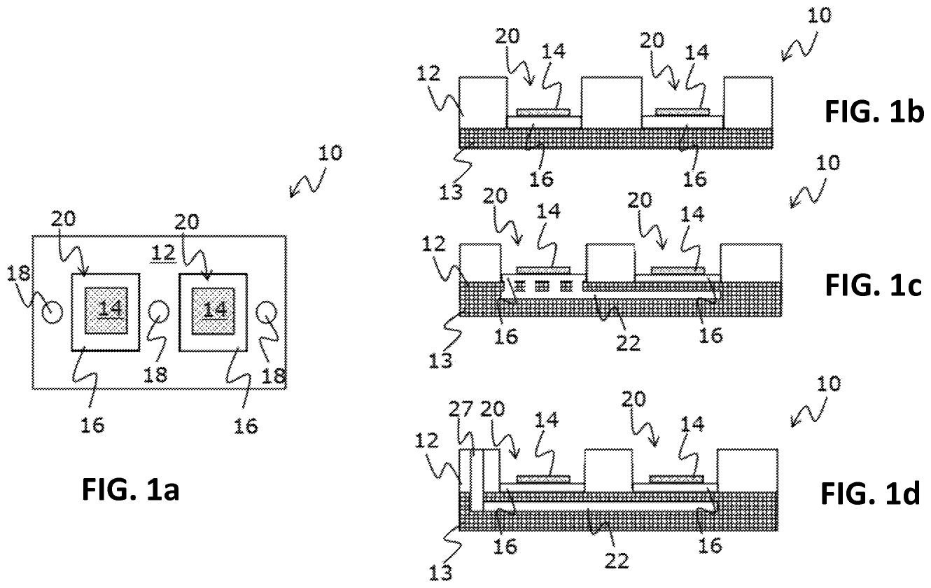

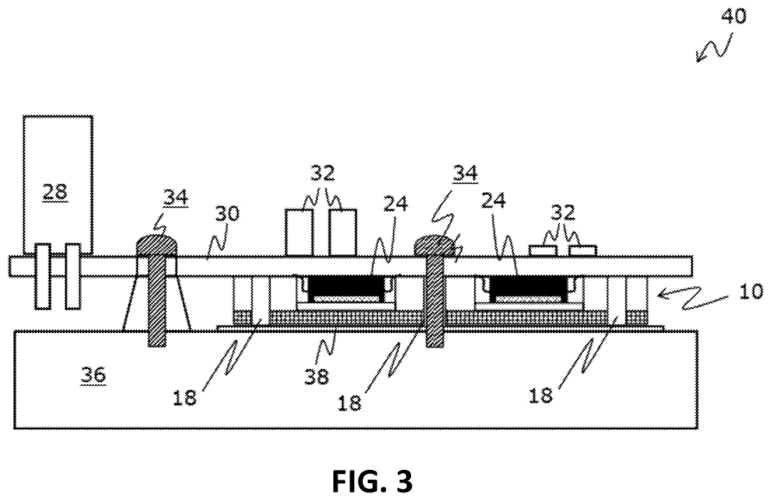

FIG. 1a schematically shows a plan view of a substrate 10. The substrate 10 has two cavities 20, in each of which a solder 14 is arranged, e.g., in the form of a solder paste or a preformed solder piece. In a respective cavity 20, a respective soldering surface 16 is arranged below the solder 14. The cavities 20 are arranged as blind recesses in a main body 12 of the substrate 10. The soldering surface 16 can be designed, e.g., as a copper layer and accordingly can have good thermal conductivity and good electrical conductivity. In the main body 12 of the substrate, recesses 18 in the form of through-recesses are provided, which can receive the mounting means 34, by means of which the substrate 10 can be mechanically connected, e.g., to a printed circuit board 30, see FIG. 3.

The substrate material of the substrate 10 can be, e.g., similar to the material of a conventional printed circuit board 30, that is, in principle can likewise comprise glass-fiber-reinforced plastic (GFRP), and alternatively or additionally can have, e.g., a higher thermal conductivity and/or a higher electrical dielectric strength than the printed circuit board 30. The substrate 10 has no conductor tracks in the example embodiments shown in FIG. 1a-1d, but is optimized for heat dissipation and/or electromagnetic shielding.

In FIGS. 1b-1d, sectional views through three embodiments of the substrate 10 are shown. In all three embodiments shown, the main body 12 of the substrate comprises an optional heat transfer layer 13. The heat transfer layer 13 can comprise a substrate material with high thermal conductivity and accordingly can dissipate heat better than the substrate material of the remaining main body 12.

In the first embodiment of the substrate 10 (FIG. 1b), a soldering surface 16 with solder 14 is arranged in each cavity 20, respectively.

In the second embodiment of the substrate 10 (FIG. 1c), the left soldering surface 16 is additionally electrically connected to a shielding layer 22. The shielding layer 22 is provided as a further layer of the substrate 10 and is arranged in the heat transfer layer 13. The shielding layer 22 extends in the heat transfer layer 13 over both cavities 20. The shielding layer 22 can be designed, e.g., as a copper layer, which can, in one embodiment, be configured in one piece with the soldering surface 16 or can be connected to the soldering surface 16 via vertically arranged vias.

In the third embodiment of the substrate 10 (FIG. 1d), a shielding layer 22 is likewise provided and extends in the heat transfer layer 13 over both cavities 20. A contact 27 of the shielding layer 22 is routed to the side of the substrate 10 toward which the cavities 20 are open. Via the contact 27, the shielding layer 22 can be electrically contacted at the surface of the substrate 10 and connected, e.g., to conductor tracks of a printed circuit board 30. The shielding layer 22 can be configured, e.g., as a copper layer.

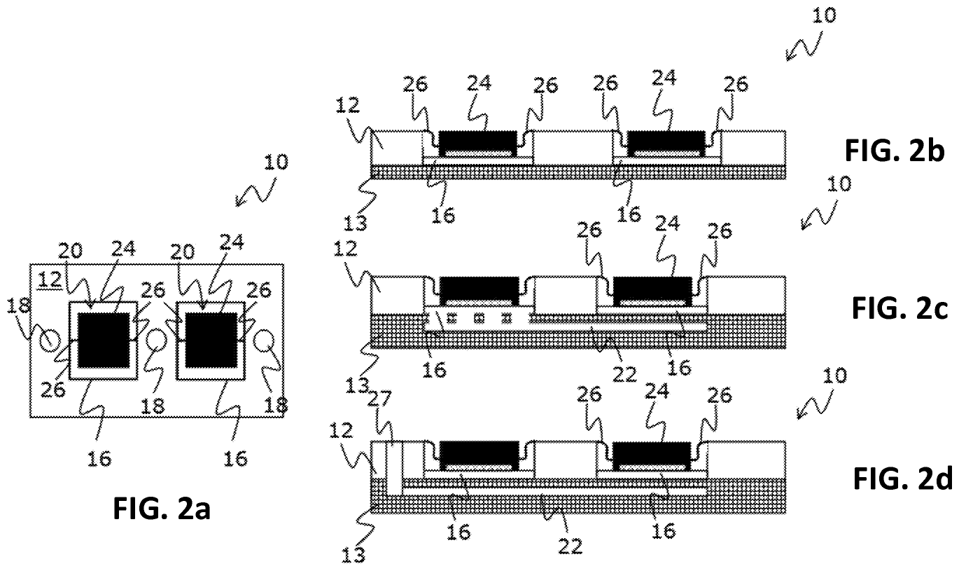

In FIGS. 2a-2d, the embodiments of the substrate 10 equipped with respective power semiconductors 24 are shown schematically. FIG. 2a shows a plan view of the substrate 10 with the power semiconductors 24 arranged in the respective cavities 20 on the respective soldering surfaces 16. The power semiconductors 24 have switching contacts 26 that are provided for contacting with a printed circuit board 30, compare FIG. 3.

In FIGS. 2b-2d, sections through the three embodiments of the substrate 10 are shown. In the respective cavities 20, the power semiconductors 24 are arranged on the respective soldering surfaces 16 with their switching contacts 26. In one embodiment, the power semiconductors 24 terminate substantially flush with the upper edges of the cavities 20. The total thickness of the substrate 10 can deviate by less than 1 mm, in one embodiment by less than 200 μm, from the thickness of the power semiconductors 24, so that, for example, the heat transfer layer 13 is less than 1 mm thick. In the region of the soldering surfaces 16, the substrate 10 can thus have a thickness of less than 1 mm, in one embodiment less than 300 μm.

FIG. 3 shows schematically a first embodiment of a power semiconductor arrangement 40, which has a printed circuit board 30 that is thermally connected to a heat sink 36 via a fastener (e.g., a screw, a rivet, or any suitable fastening element or structure) 34.

This first embodiment of the power semiconductor arrangement 40 comprises the first embodiment of the substrate 10. The substrate 10 can also comprise recesses 18, as shown in the embodiments of FIG. 1a and FIG. 2a. These recesses 18 can then serve alternatively or additionally to receive the fastener 34 or further fastener 34.

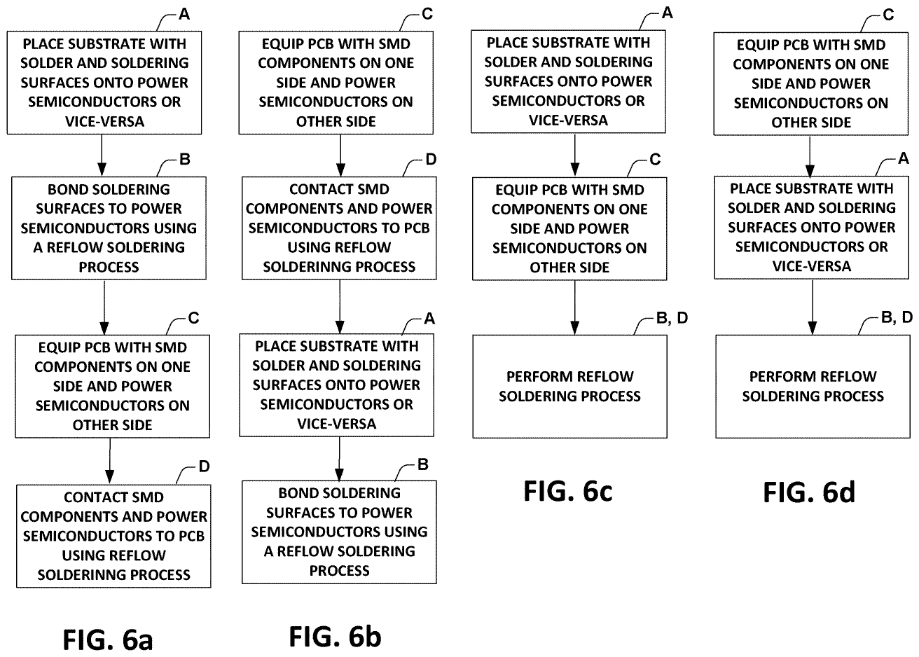

In one embodiment, the printed circuit board 30 is equipped with components on two sides. On one side, the printed circuit board 30 is equipped with an optional THT (Through-Hole Technology) component 28 and a plurality of SMD components 32. On the other side, the printed circuit board 30 is at least equipped with the power semiconductor 24. The switching contacts 26 of the power semiconductor 24 are contacted with the printed circuit board 30, e.g., by a soldering process, as described below with respect to FIG. 6.

The power semiconductors 24 of the first embodiment of the power semiconductor arrangement 40 shown in FIG. 3 are equipped on the first embodiment of the substrate 10. The underside of the substrate 10, optionally configured as heat transfer layer 13, is thermally connected to the heat sink 36 via thermally conductive paste 38. The power semiconductors 24, in one embodiment, are configured as TSC SMD power semiconductors 24. On their contacting side (in FIG. 3 on the upper side), they are connected with their switching contacts 26 to the printed circuit board 30. On their heat-dissipating side (in FIG. 3 on the underside), they are connected to the substrate 10 via the soldering surfaces 16.

The power semiconductors 24 can be connected to the printed circuit board 30 and the substrate 10 by means of one of the methods described with respect to FIG. 6.

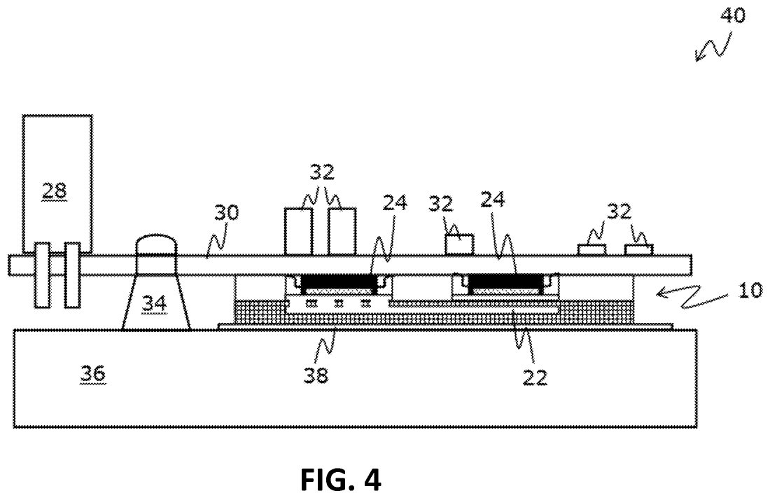

FIG. 4 schematically shows a second embodiment of the power semiconductor arrangement 40, which comprises the printed circuit board 30 that is mechanically and thermally connected to the heat sink 36 via the fastener 34.

The second embodiment shown of the power semiconductor arrangement 40 comprises the second embodiment of the substrate 10, compare embodiment in FIG. 1c and FIG. 2c. The substrate 10 can comprise recesses 18, as shown in the example embodiments of FIG. 1a and FIG. 2a. These recesses 18 can then serve alternatively or additionally to receive the fastener 34 or further fastener 34.

The printed circuit board 30 is equipped with components on both sides. On one side, the printed circuit board 30 is equipped with an optional THT component 28 and a plurality of SMD components 32. On the other side, the printed circuit board 30 is equipped with the power semiconductor 24. The switching contacts 26 of the power semiconductor 24 are contacted with the printed circuit board 30, e.g., by a soldering process, as described with respect to FIG. 6.

The power semiconductors 24 of the second embodiment of the power semiconductor arrangement 40 according to FIG. 4 are equipped on the second embodiment of the substrate 10 according to FIG. 1c or FIG. 2c, which comprises the shielding layer 22 connected to one of the soldering surfaces. The shielding layer 22 is arranged in the heat transfer layer 13. The shielding layer 22 and the heat transfer layer 13 extend longitudinally relative to one another and are, in one embodiment, parallel to one another. The substrate 10 is thermally connected to the heat sink 36 via thermally conductive paste 38. The power semiconductors 24 are configured as TSC SMD power semiconductors 24 and connected, on their contacting side, via their switching contacts 26 to the printed circuit board 30, for example, to conductor tracks (not shown) of the printed circuit board 30. On their heat-dissipating side, the power semiconductors 24 are connected to the substrate 10 via the soldering surfaces 16.

The shielding layer 22 is, in one embodiment, electrically connected to one of the DC voltage potentials DC+, DC−, or the center potential M in order to dissipate capacitively coupled interference currents (=common-mode interference), which can occur between the switching-node potential of the particular power semiconductor 24 and the ground potential. Due to the connection of the shielding layer 22 to M, DC−, or DC+, the potential of the shielding layer 22 hardly varies relative to ground, so that common-mode interference can be significantly reduced.

In second embodiment of the substrate 10 as shown in FIG. 4, the connection of the shielding layer 22 to a substantially constant potential M, DC−, or DC+ is effected via the soldering surface 16 and the power semiconductor 24 connected thereto, while the common substrate 10 accommodates a plurality of power semiconductors 24. In this second embodiment, the potential switched by the power semiconductor 24 connected to the shielding layer 22 is, in one embodiment, a substantially constant potential, whereas the potential switched by the further power semiconductor 24 arranged on the same substrate 10 can be a jumping potential. Due to the fact that the substantially constant potential of the power semiconductor 24 connected to the shielding layer 22 is extended as a “stabilized” shielding layer 22 under the other power semiconductor or semiconductors 24, the jumping potential of the other power semiconductor 24 is shielded as well relative to the heat sink 36, which is at ground potential, and capacitive interference currents can be dissipated via the shielding layer 22 and thereby reduced.

Power losses at the power semiconductors 24 can be reduced and the thermal path can be shortened if suitable additional layers are inserted into the substrate 10. For example, thermally high-performance prepregs comprising an insulating glass-fiber resin layer can be implemented as an additional layer. Prepregs, short for preimpregnated fibers, are textile fiber semi-finished products that are preimpregnated with special reactive resins. The shielding layer 22 can moreover additionally be used for heat spreading.

The connection of the power semiconductors 24 to the printed circuit board 30 and the substrate 10 can be effected by means of one of the methods described with respect to FIG. 6.

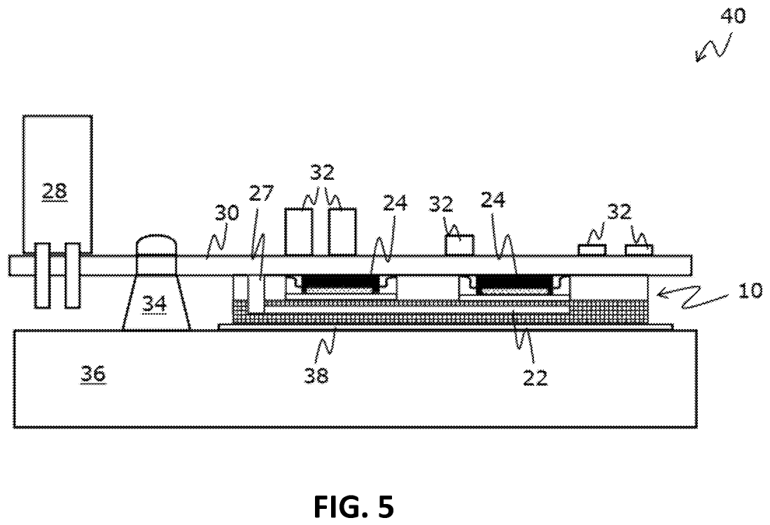

FIG. 5 schematically shows a third embodiment of the power semiconductor arrangement 40, which comprises the printed circuit board 30, which is mechanically and thermally connected to the heat sink 36 via the fastener 34.

The third embodiment of the power semiconductor arrangement 40 according to FIG. 5 comprises the third embodiment of the substrate 10, compare FIG. 1d and FIG. 2d. The substrate 10 can also comprise recesses 18, as shown in the example embodiments of FIG. 1a and FIG. 2a. These recesses 18 can then serve alternatively or additionally to receive the fastener 34 or further fastener 34.

The printed circuit board 30 is equipped with components on both sides. On one side, the printed circuit board 30 is equipped with an optional THT component 28 and a plurality of SMD components 32. On the other side, the printed circuit board 30 is equipped with the power semiconductor 24. The switching contacts 26 of the power semiconductor 24 are contacted with the printed circuit board 30, e.g., by a soldering process, as described with respect to FIG. 6.

The power semiconductors 24 of the third embodiment of the power semiconductor arrangement 40 as shown in FIG. 4 are equipped on the third embodiment of the substrate 10 comprising the shielding layer 22, which has a contact at the edge of the substrate 10 and is, in one embodiment, electrically contacted with the printed circuit board 30. The shielding layer 22 can be arranged in a heat transfer layer 13. The shielding layer 22 and the heat transfer layer 13 extend longitudinally relative to one another and are, for example, parallel to one another. The substrate 10 is thermally connected to the heat sink 36 via thermally conductive paste 38. The power semiconductors 24 are configured as TSC SMD power semiconductors 24 and connected, on their contacting side, via their switching contacts 26 to the printed circuit board 30, for example, to conductor tracks (not shown) of the printed circuit board 30. On their heat-dissipating side, the power semiconductors 24 are connected to the substrate 10 via the soldering surfaces 16.

The shielding layer 22 is connected via a contact 27, which is configured, for example, as a via in the substrate 10, to a DC voltage potential DC+, DC−, or a center potential M of the circuit on the printed circuit board 30, in order to dissipate capacitively coupled interference currents (=common-mode interference), which can occur between the switching-node potential of the particular power semiconductor 24 and the heat sink 36, which is usually grounded. The potential of the shielding layer 22 is connected to M, DC−, or DC+ and is thus configured to hardly vary relative to ground, such that common-mode interference can be significantly reduced.

In the third embodiment of the power semiconductor arrangement 40 according to FIG. 5, the connection of the shielding layer 22 to M, DC−, or DC+ is effected directly via the contact 27. Thus, the shielding layer 22 is a potential-stabilized layer in the substrate 10, which causes the potential of the cooling surface, i.e., the heat-dissipating side of the TSC SMD power semiconductor 24, to be shielded. The potential of the heat-dissipating side of the TSC SMD power semiconductor 24 can be, e.g., in an inverter, a jumping switching-node potential of a half-bridge of the inverter. This jumping potential can be shielded by the shielding layer 22 from the heat sink 36, which is, e.g., at ground potential. Capacitive interference currents can be dissipated more directly via the shielding layer 22 than, e.g., with conventional filter components in DC or AC lines of an inverter, such that the latter can be dimensioned more cost-effectively and/or smaller.

Power losses at the power semiconductors 24 can be reduced and the thermal path can be shortened if suitable additional layers are inserted into the substrate 10. For example, thermally high-performance prepregs comprising an insulating glass-fiber resin layer can be implemented as an additional layer. The shielding layer 22 can moreover additionally be used for heat spreading.

The connection of the power semiconductors 24 to the printed circuit board 30 and the substrate 10 can be effected by means of one of the methods described with respect to FIG. 6.

FIGS. 6a-6d schematically show embodiments of a method for producing the power semiconductor arrangement 40.

In a first embodiment of the method, in FIG. 6a, act A comprises placing onto the power semiconductors 24, e.g., by a pick and place machine, the substrate 10 provided with solder 14 on the soldering surfaces 16. Alternatively, in act A the power semiconductors 24 can be placed onto the substrate 10. The solder 14 can be, e.g., solder paste, and the soldering surfaces 16 can be, e.g., SMT adapter pads printed with the solder paste.

In act B, the soldering surfaces 16 are bonded to the power semiconductors 24, e.g. by means of a reflow soldering process.

In act C, the printed circuit board 30 is equipped with the SMD components 32 on one side and with the power semiconductors 24, e.g., TSC SMD power semiconductors 24, on the other side, wherein at least one of the power semiconductors 24 is bonded to a respective substrate 10.

In act D, the equipped SMD components 32 and power semiconductors 24 are contacted with the printed circuit board 30 by a soldering process, e.g., a reflow soldering process.

In a second embodiment of the method, shown in FIG. 6b, in act C the printed circuit board 30 is equipped with the SMD components 32 on one side and with the power semiconductors 24, e.g., TSC SMD power semiconductors 24, on the other side.

In act D, the equipped SMD components 32 and power semiconductors 24 are contacted with the printed circuit board 30 by a soldering process, e.g., a reflow soldering process.

In act A, the substrate 10 provided with solder 14 on the soldering surfaces 16 is placed onto the power semiconductors 24, e.g., by a pick-and-place machine. Alternatively, the power semiconductors 24 are placed onto the substrate 10. The solder 14 can be, e.g., solder paste, and the soldering surfaces 16 can be, e.g., SMT adapter pads printed with the solder paste.

In act B, the soldering surfaces 16 can then be bonded to the power semiconductors 24, e.g. by means of a reflow soldering process.

In the third embodiment of the method of FIG. 6c, in act A the substrate 10 is placed onto the power semiconductors 24 or the power semiconductors 24 are placed onto the substrate 10. In act C the printed circuit board 30 is then equipped with the SMD components 32 on one side and with the power semiconductors 24, e.g., TSC SMD power semiconductors 24, on the other side, wherein at least one of the power semiconductors 24 is in close contact with a respective substrate 10.

In combined acts B and D a reflow soldering process, which bonds all relevant components to the substrate 10 and the printed circuit board 30, respectively, is performed.

In the fourth embodiment of the method of FIG. 6d, in act C), the printed circuit board 30 is equipped with the SMD components 32 on one side and with the power semiconductors 24, e.g., TSC SMD power semiconductors 24, on the other side. In act A the substrate 10 is then placed onto the power semiconductors 24.

In combined acts B and D a reflow soldering process, which bonds the components to the substrate 10 and the printed circuit board 30, respectively, is performed.

Example 1: A method for producing a power semiconductor arrangement, wherein the power semiconductor arrangement comprises at least one SMD power semiconductor and a substrate with at least one soldering surface, and wherein a main body of the substrate comprises at least one substrate material having a high thermal conductivity and/or a high electrical dielectric strength, and wherein the substrate has a heat-dissipating and/or electromagnetically shielding effect with respect to the SMD power semiconductor, wherein the method comprises equipping the substrate with the at least one SMD power semiconductor by placing the SMD power semiconductor onto the soldering surface, or equipping the substrate by placing the substrate with the soldering surface onto the SMD power semiconductor.

Example 2. The method according to Example 2, wherein after equipping the substrate, the SMD power semiconductor is bonded to the soldering surface by means of a solder arranged on the soldering surface by a soldering process.

Example 3. The method according to Example 3, wherein the soldering surface is connected to a side of the SMD power semiconductor that is provided for dissipating power loss of the SMD power semiconductor, wherein the side of the SMD power semiconductor provided for heat dissipation lies opposite a contacting side with switching contacts of the SMD power semiconductor.

Example 4. The method of Example 1, further comprising equipping a printed circuit board with the SMD power semiconductor by placing the at least one SMD power semiconductor onto the printed circuit board.

Example 5. The method of Example 4, wherein after equipping the printed circuit board, the SMD power semiconductor is bonded to the printed circuit board by a soldering process.

Example 6. The method of Example 5, wherein the soldering process for bonding the SMD power semiconductor to the soldering surface and/or for bonding the SMD power semiconductor to the printed circuit board comprises a reflow soldering process.

Example 7. The method of Example 5, wherein the soldering process is performed before or after the soldering process for bonding the SMD power semiconductor to the printed circuit board, or both soldering processes are performed in one step.

Example 8. The method of Example 4, wherein the step of equipping the printed circuit board with the SMD power semiconductor is carried out before or after the step of equipping the substrate with the at least one SMD power semiconductor.

What is claimed is:

1. A substrate having a soldering surface,
wherein the substrate is configured to be equipped with a surface mounted device (SMD) power semiconductor,
wherein, for equipping the substrate with the SMD power semiconductor, the soldering surface is configured to be bonded to the SMD power semiconductor by a soldering process, and wherein the soldering surface comprises a solder which is either a solder paste or a preformed solder piece,
wherein a main body of the substrate comprises at least one substrate material having a high thermal conductivity and/or a high electrical dielectric strength, and wherein the substrate is designed to have a heat-dissipating and/or electromagnetically shielding effect with respect to the SMD power semiconductor.

2. The substrate according to claim 1, wherein the substrate comprises a plurality of separate soldering surfaces which are provided for connection to different SMD power semiconductors.

3. The substrate according to claim 1, wherein the at least one substrate material comprises ceramic, plastic and/or composite material.

4. The substrate according to claim 1, wherein the soldering surface comprises a copper layer.

5. The substrate according to claim 1, wherein the soldering surface is arranged in a cavity of the substrate.

6. The substrate according to claim 1, wherein a thickness of the substrate differs by less than 1 mm from the thickness of the SMD power semiconductor, wherein the substrate has a uniform thickness or has different thicknesses over its extent, and wherein the thickness of the substrate at the soldering surface is less than 1 mm.

7. The substrate according to claim 1, wherein the substrate consists substantially of an epoxy resin-glass fabric composite material, and comprises a plurality of layers with different thermal conductivities.

8. The substrate according to claim 7, wherein the substrate comprises a shielding layer configured to provide electromagnetic shielding, wherein the shielding layer comprises a metal, and wherein the shielding layer is arranged in the substrate between the soldering surface and a side of the substrate opposite the power semiconductor.

9. The substrate according to claim 8, wherein the substrate comprises at least two soldering surfaces, and wherein the shielding layer extends over the at least two soldering surfaces.

10. The substrate according to claim 8, wherein the substrate comprises, on a side of the SMD power semiconductor, an electrical contact to the shielding layer.

11. The substrate according to claim 8, wherein the shielding layer is electrically connected to one of the soldering surfaces.

12. The substrate according to claim 11, wherein the shielding layer is a copper layer configured in one piece with the soldering surface electrically connected to the shielding layer.

13. A power semiconductor arrangement comprising:
at least one SMD power semiconductor,
a substrate having a soldering surface, wherein the substrate is configured to be equipped with a SMD power semiconductor, wherein, for equipping the substrate with the SMD power semiconductor, the soldering surface is configured to be bonded to the SMD power semiconductor by a soldering process, and wherein the soldering surface comprises a solder which is either a solder paste or a preformed solder piece, wherein a main body of the substrate comprises at least one substrate material having a high thermal conductivity and/or a high electrical dielectric strength, and wherein the substrate is designed to have a heat-dissipating and/or electromagnetically shielding effect with respect to the SMD power semiconductor, and
at least one heat sink thermally connected to the substrate.

14. The power semiconductor arrangement of claim 13, wherein the soldering surface is provided for connection to a side of the SMD power semiconductor that is provided for heat dissipation, and wherein the side of the SMD power semiconductor provided for heat dissipation lies opposite a contacting side with switching contacts of the SMD power semiconductor.

15. The power semiconductor arrangement according to claim 13, further comprising a printed circuit board, with which the at least one SMD power semiconductor is electrically conductively connected via switching contacts.

16. The power semiconductor arrangement according to claim 13, wherein the at least one SMD power semiconductor is bonded to the soldering surface in at least one cavity of the substrate, and wherein the SMD power semiconductor is electrically conductively connected on a side opposite the substrate to a printed circuit board, and wherein the substrate bears against the printed circuit board in regions different from the at least one cavity.

17. The power semiconductor arrangement according to claim 13, wherein a shielding layer is electrically connected to a potential of the power semiconductor arrangement which is substantially constant with respect to a potential of an associated heat sink during operation.

18. An inverter comprising:
a power semiconductor arrangement, comprising:
at least one SMD power semiconductor,
a substrate having a soldering surface, wherein the substrate is configured to be equipped with a SMD power semiconductor, wherein, for equipping the substrate with the SMD power semiconductor, the soldering surface is configured to be bonded to the power semiconductor by a soldering process, and wherein the soldering surface comprises a solder which is either a solder paste or a preformed solder piece, wherein a main body of the substrate comprises at least one substrate material having a high thermal conductivity and/or a high electrical dielectric strength, and wherein the substrate is designed to have a heat-dissipating and/or electromagnetically shielding effect with respect to the SMD power semiconductor,
at least one heat sink thermally connected to the substrate, and
a DC/DC or DC/AC circuit, which comprises the at least one SMD power semiconductor,
wherein the inverter has a rated electrical power of at least one kilowatt and the at least one SMD power semiconductor is designed as a power switch for switching a maximum electrical current of at least 10 amperes at a maximum voltage of at least 500 volts.

19. The inverter according to claim 18, wherein the substrate comprises at least two power switches comprising SMD power semiconductors, and wherein a shielding layer arranged in the substrate between the soldering surface and a side of the substrate opposite the power semiconductor extends over the at least two power switches.

20. The inverter according to claim 18, wherein one of the at least two power switches is configured to switch a substantially constant potential that is connected to its switching contacts, and is electrically connected on its side provided for heat dissipation to a shielding layer, wherein an other of the at least two power switches is designed for switching a variable potential that jumps between different potential values during operation of the inverter.
